(19) United States
(12) Patent Application Publication
(10) Pub. No.: US 2025/0020726 A1
(43) Pub. Date: Jan. 16, 2025

(54) METHOD AND SYSTEM FOR VERIFYING ELECTRIC VEHICLE BATTERY STATE OF HEALTH

(71) Applicant: Dana Heavy Vehicle Systems Group, LLC, Maumee, OH (US)

(72) Inventors: Joseph BERTRAND, Canton, MI (US); Aneet SOUNDARARAJ, Ann Arbor, MI (US)

(21) Appl. No.: 18/352,565

(22) Filed: Jul. 14, 2023

(51) Int. Cl. G01R 31/389; B60L 58/16; G01R 31/3842

(52) U.S. Cl. CPC G01R 31/389; B60L 58/16; G01R 31/3842

(57) ABSTRACT

Methods and systems for managing operation of a traction battery pack of a vehicle are described. The methods and systems may be applied to improve estimation of battery state of health, battery state of charge, and battery DC resistance. The approach may be applied when a traction battery is being charged.

### TECHNICAL FIELD

The present disclosure relates to a method and system for providing closed loop estimates of battery state of health and direct current (DC) resistance.

### BACKGROUND AND SUMMARY

A traction battery of a vehicle may include a battery pack that is comprised of battery cells that are arranged in series and in parallel. The battery pack may be charged and discharged while the vehicle is operating. In addition, the battery pack may be charged while the vehicle is inactive. A vehicle may report out a battery state of charge (SOC) and a battery state of health (SOH). The battery state of charge may be described as a ratio of an amount of charge stored in a battery to the total charge capacity of the battery multiplied by one hundred. The battery state of health may be described as a ratio of a maximum charge capacity of a battery to a rated charge capacity of the battery (e.g., the maximum charge that a battery may store when it is new) multiplied by one hundred.

Many battery manufacturers include DC resistance in the state of health (SOH) calculated value. Some battery manufactures express state of power (SOP). This is a measure of the maximum pulse or continuous discharge current allowed. State of Power is typically communicated as a percentage compared to the peak rated discharge power that does not cause the battery to exceed its voltage limits. Voltage limits generally follows Ohms Law: Vmax=V (rested cell)+ (Imax/DC resistance). As DC resistance rises, the allowed current is reduced to avoid overvoltage condition. An example battery pack may allow 100 A as rated current. Due to the rise in DC resistance, the peak current may be reduced to 90 A. In this case, SOP would be communicated as (90 A/100 A=) 90% SOP.

Battery manufacturers may analyze battery chemistries to estimate an expected life of a battery. In a laboratory, a battery manufacturer may subject a battery charging/discharging, temperature changes, and other factors that may influence battery age to estimate battery life. The battery manufacturers may measure battery cell capacity changes and changes in the internal resistance of the battery. From these measurements, the manufacturer may generate one or more formulas for estimating battery age that may be applied to batteries that are in use outside of a laboratory. In particular, the one or more formulas may be incorporated into a battery management system (BMS) so that the BMS may forecast battery ageing over the life of the battery. The BMS may output an estimated battery SOH value to other vehicle systems. The estimated battery SOH value may be based on several control parameters, such as but not limited to ambient temperature, battery age, etc.

Battery SOH values that are estimated by the BMS may have limited accuracy due to the estimates being feedforward or open loop estimates that lack feedback. The battery SOH estimates may be further limited by the original test factors that may not compensate for manufacturing variation, changes in the battery after installation, and battery temperatures that may not be monitored while the vehicle is off. Additionally, in use estimates of battery SOH that are based on lab conditions may be less accurate than battery SOH estimates that are conducted under lab conditions using the lab generated formulas. For at least these reasons, it may be desirable to provide an improved way to estimate battery SOH.

The inventor herein has recognized the above-mentioned issues and has developed a method for operating a battery of a vehicle, comprising: estimating a state of health of the battery based on a first resistance value and a second resistance value; and adjusting a maximum output of the battery in response to the state of health.

By correcting the DC resistance component of the battery state of health estimate, it may be possible to provide the technical result of generating a battery state of health that includes feedback compensation. The feedback compensation may provide a more accurate estimate of battery state of health. The corrected battery state of health may be a basis for freeing or constraining battery pack output.

The present description may provide several advantages. In particular, the approach may provide a more accurate estimate of battery pack state of health by incorporating feedback correction. In addition, the approach may provide accurate estimates of battery DC resistance and battery state of health. Further, the approach may be implemented in a vehicle under real world conditions.

It is to be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 is an illustration of an example vehicle that includes an electric energy storage system.

FIG. 2 shows a method for determining DC resistance of an electric energy storage system.

FIG. 3 shows a method for correcting SOH and DCR estimates.

FIG. 4 shows an example relationship between DCR and SOH.

FIG. 5 shows a block diagram for generating an open loop estimate of DCR.

FIG. 6 shows an example baseline battery resistance table.

### DETAILED DESCRIPTION

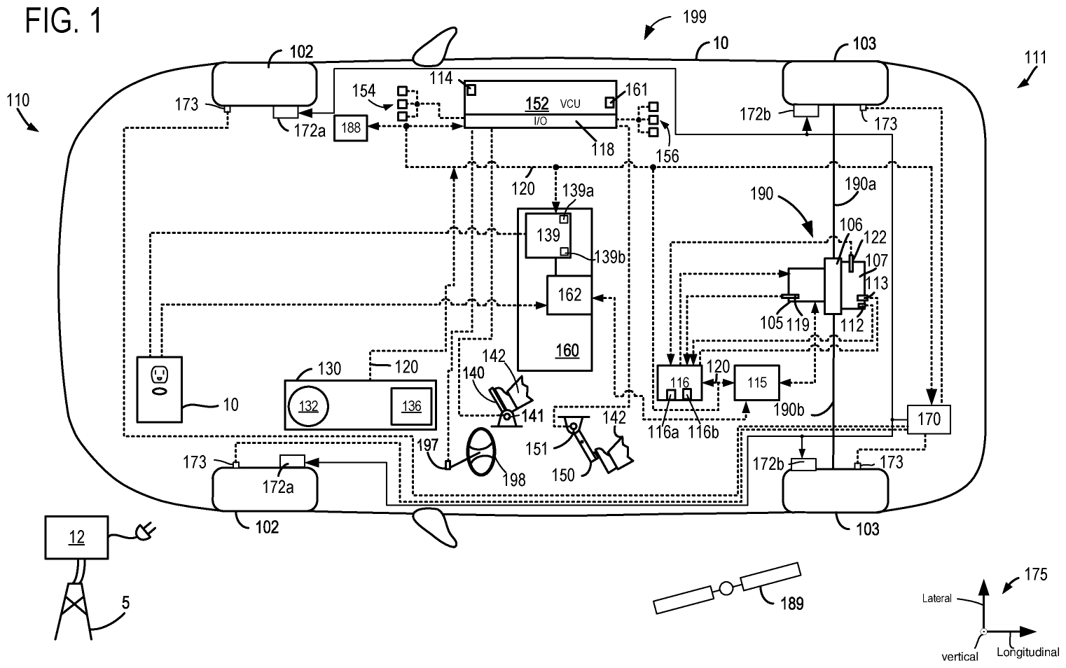

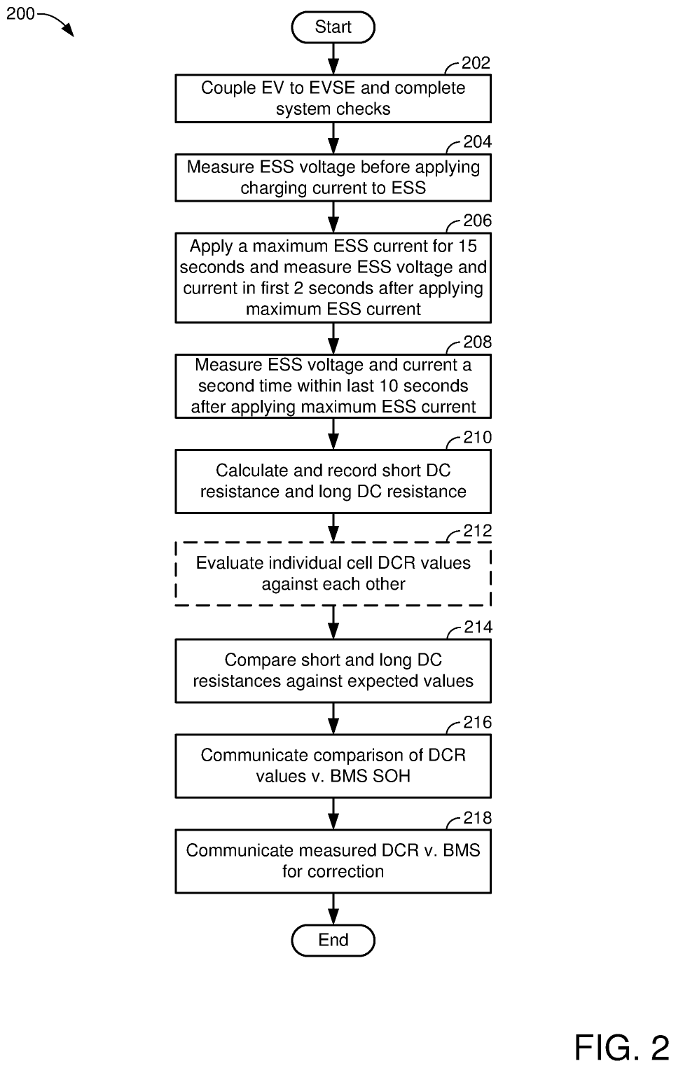

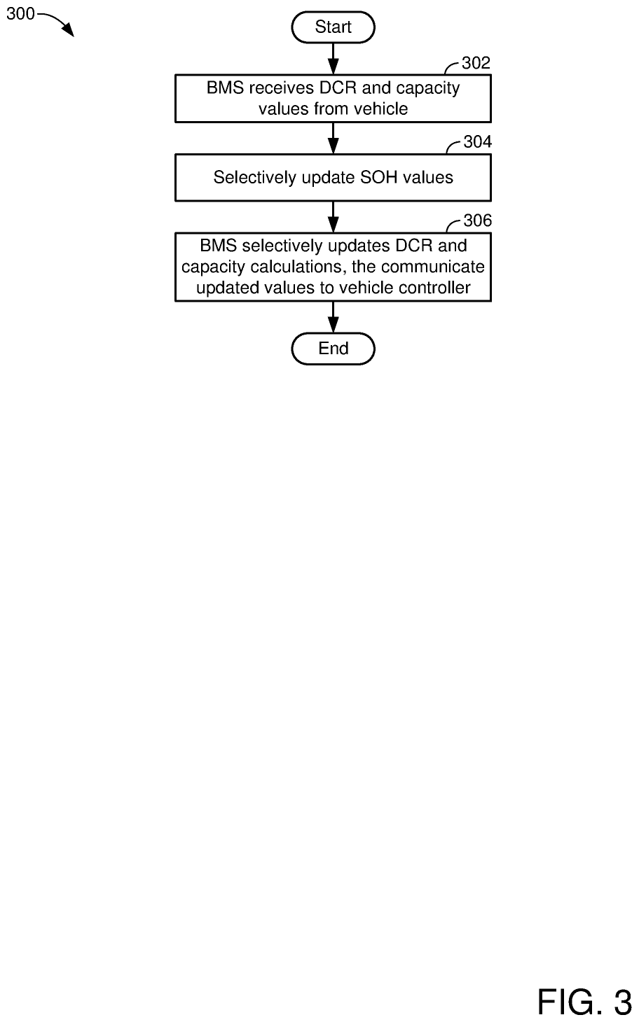

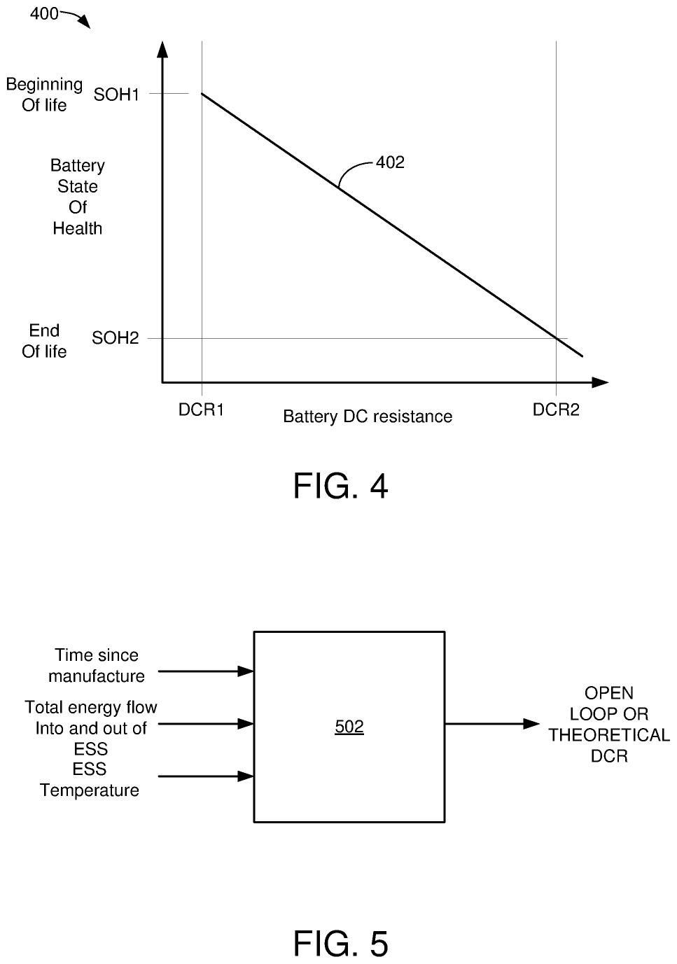

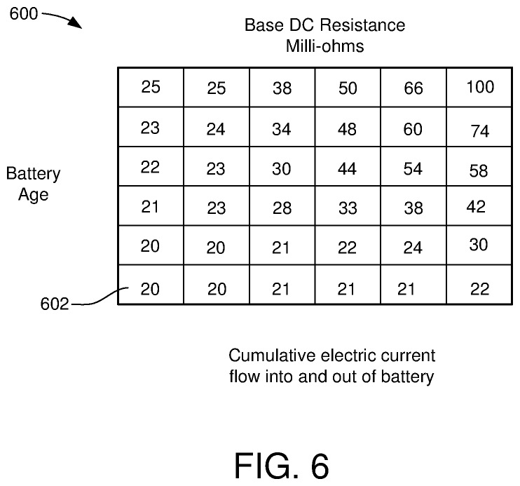

A method and system for operating a battery pack for a vehicle is described. The method and system are suitable for electric and hybrid vehicles. In one example, the method and system generate a state of battery health according to a DC resistance of the battery pack. The state of battery health may be broadcast to other vehicle systems and output of the battery pack may be constrained based on the DC resistance value. The method and system may be applied to a vehicle of the type that is shown in FIG. 1. The methods of FIGS. 2 and 3 may be included in a vehicle to generate the state of health value. FIG. 4 shows a relationship between battery DC resistance and battery state of health. FIG. 5 shows a block diagram for generating a feedforward or open loop battery DC resistance estimate and FIG. 6 shows an example baseline battery resistance table.

FIG. 1 illustrates an example vehicle propulsion system 199 for vehicle 10. A front end 110 of vehicle 10 is indicated and a rear end 111 of vehicle 10 is also indicated. Vehicle 10 travels in a forward direction when front end leads movement of vehicle 10. Vehicle 10 travels in a reverse direction when rear end leads movement of vehicle 10. Vehicle propulsion system 199 includes a propulsion source 105 (e.g., an electric machine), but in other examples two or more propulsion sources may be provided. In one example, propulsion source 105 may be an electric machine that operates as a motor or generator. The propulsion source 105 is fastened to the electrified axle 190. In FIG. 1 mechanical connections between the various components are illustrated as solid lines, whereas electrical connections between various components are illustrated as dashed lines.

Vehicle propulsion system 199 includes an electrified axle 190 (e.g., an axle that includes an integrated electric machine that provides propulsive effort for the vehicle). Electrified axle 190 may include two half shafts, including a first or right haft shaft 190a and a second or left half shaft 190b. Vehicle 10 further includes front wheels 102 and rear wheels 103.

The electrified axle 190 may be an integrated axle that includes differential gears 106, gear set 107, and propulsion source 105. Electrified axle 190 may include a first speed sensor 119 for sensing a speed of propulsion source 105, a second speed sensor 122 for sensing a speed of an output shaft (not shown), a first clutch actuator 112, and a clutch position sensor 113. Electric power inverter 115 is electrically coupled to propulsion source 105. An axle control unit 116 is electrically coupled to sensors and actuators of electrified axle 190.

Propulsion source 105 may transfer mechanical power to or receive mechanical power from gear set 107. As such, gear set 107 may be a multi-speed gear set that may shift between gears when commanded via axle control unit 116. Axle control unit 116 includes a processor 116a and memory 116b. Memory 116b may include read only memory, random access memory, and keep alive memory. Gear set 107 may transfer mechanical power to or receive mechanical power from differential gears 106. Differential gears 106 may transfer mechanical power to or receive mechanical power from rear wheels 103 via right half shaft 190a and left half shaft 190b. Propulsion source 105 may consume alternating current (AC) electrical power provided via electric power inverter 115. Alternatively, propulsion source 105 may provide AC electrical power to electric power inverter 115. Electric power inverter 115 may be provided with high voltage direct current (DC) power from battery 160 (e.g., a traction battery, which also may be referred to as a battery pack). Electric power inverter 115 may convert the DC electrical power from battery 160 into AC electrical power for propulsion source 105. Alternatively, electric power inverter 115 may be provided with AC power from propulsion source 105. Electric power inverter 115 may convert the AC electrical power from propulsion source 105 into DC power to store in battery 160.

Battery 160 may periodically receive electrical energy from a power source such as a stationary power grid (not shown) residing external to the vehicle (e.g., not part of the vehicle). As a non-limiting example, vehicle propulsion system 199 may be configured as a plug-in electric vehicle (EV), whereby electrical energy may be supplied to battery 160 via the power grid (not shown).

Battery 160 may include a BMS controller 139 (e.g., a battery management system controller) and an electrical power distribution box 162. Battery controller 139 may provide charge balancing between energy storage elements (e.g., battery cells) and communication with other vehicle controllers (e.g., vehicle control unit 152). BMS controller 139 also includes memory 139a (e.g., read-only memory and random access memory) a central processing unit 139b.

Vehicle 10 may include a vehicle control unit (VCU) controller 152 that may communicate with electric power inverter 115, axle control unit 116, friction or foundation brake controller 170, global positioning system (GPS) 188, BMS controller 139, and dashboard 130 and components included therein via controller area network (CAN) 120. VCU 152 includes memory 114, which may include read-only memory (ROM or non-transitory memory) and random access memory (RAM). VCU also includes a digital processor or central processing unit (CPU) 161, and inputs and outputs (I/O) 118 (e.g., digital inputs including counters, timers, and discrete inputs, digital outputs, analog inputs, and analog outputs). VCU may receive signals from sensors 154 and provide control signal outputs to actuators 156. Sensors 154 may include but are not limited to lateral accelerometers, longitudinal accelerometers, yaw rate sensors, inclinometers, temperature sensors, battery voltage and current sensors, and other sensors described herein. Additionally, sensors 154 may include steering angle sensor 197, driver demand pedal position sensor 141, vehicle range finding sensors including radio detection and ranging (RADAR), light detection and ranging (LIDAR), sound navigation and ranging (SONAR), and brake pedal position sensor 151. Actuators may include but are not constrained to inverters, transmission controllers, display devices, human/machine interfaces, friction braking systems, and battery controller described herein.

Driver demand pedal position sensor 141 is shown coupled to driver demand pedal 140 for determining a degree of application of driver demand pedal 140 by human 142. Brake pedal position sensor 151 is shown coupled to brake pedal 150 for determining a degree of application of brake pedal 150 by human 142. Steering angle sensor 197 is configured to determine a steering angle according to a position of steering wheel 198.

Vehicle propulsion system 199 is shown with a global position determining system 188 that receives timing and position data from one or more GPS satellites 189. Global positioning system may also include geographical maps in ROM for determining the position of vehicle 10 and features of roads that vehicle 10 may travel on.

Vehicle propulsion system 199 may also include a dashboard 130 that an operator of the vehicle may interact with. Dashboard 130 may include a display system 132 configured to display information to the vehicle operator. Display system 132 may comprise, as a non-limiting example, a touchscreen, or human machine interface (HMI), display which enables the vehicle operator to view graphical information as well as input commands. In some examples, display system 132 may be connected wirelessly to the internet (not shown) via VCU 152. As such, in some examples, the vehicle operator may communicate via display system 132 with an internet site or software application (app) and VCU 152.

Dashboard 130 may further include an operator interface 136 via which the vehicle operator may adjust the operating status of the vehicle. Specifically, the operator interface 136 may be configured to activate and/or deactivate operation of the vehicle driveline (e.g., propulsion source 105) based on an operator input. Further, an operator may request an axle mode (e.g., park, reverse, neutral, drive) via the operator interface. Various examples of the operator interface 136 may include interfaces that require a physical apparatus, such as a key, that may be inserted into the operator interface 136 to activate the electrified axle 190 and propulsion source 105 and to turn on the vehicle 10 or may be removed to shut down the electrified axle and propulsion source 105 to turn off vehicle 10. Electrified axle 190 and propulsion source 105 may be activated via supplying electric power to propulsion source 105 and/or electric power inverter 115. Electrified axle 190 and electric machine may be deactivated by ceasing to supply electric power to electrified axle 190 and propulsion source 105 and/or electric power inverter 115. Still other examples may additionally or optionally use a start/stop button that is manually pressed by the operator to start or shut down the electrified axle 190 and propulsion source 105 to turn the vehicle on or off. In other examples, a remote electrified axle or electric machine start may be initiated remote computing device (not shown), for example a cellular telephone, or smartphone-based system where a user's cellular telephone sends data to a server and the server communicates with the vehicle controller 152 to activate the electrified axle 190 including an inverter and electric machine. Spatial orientation of vehicle 10 is indicated via axes 175.

Vehicle 10 is also shown with a foundation or friction brake controller 170. Friction brake controller 170 may selectively apply and release friction brakes (e.g., 172a and 172b) via allowing hydraulic fluid to flow to the friction brakes. The friction brakes may be applied and released so as to avoid locking of the friction brakes to front wheels 102 and rear wheels 103. Wheel position or speed sensors 173 may provide wheel speed data to friction brake controller 170. Vehicle propulsion system 199 may provide torque to rear wheels 103 to propel vehicle 10.

A human or autonomous driver may request a driver demand wheel torque, or alternatively a driver demand wheel power, via applying driver demand pedal 140 or via supplying a driver demand wheel torque/power request to vehicle controller 152. Vehicle controller 152 may then demand a torque or power from propulsion source 105 via commanding axle control unit 116. Axle control unit 116 may command electric power inverter 115 to deliver the driver demand wheel torque/power via electrified axle 190 and propulsion source 105. Electric power inverter 115 may convert DC electrical power from battery 160 into AC power and supply the AC power to propulsion source 105. Propulsion source 105 rotates and transfers torque/power to gear set 107. Gear set 107 may supply torque from propulsion source 105 to differential gears 106, and differential gears 106 transfer torque from propulsion source 105 to rear wheels 103 via half shafts 190a and 190b.

During conditions when the driver demand pedal is fully released, vehicle controller 152 may request a small negative or regenerative braking power to gradually slow vehicle 10 when a speed of vehicle 10 is greater than a threshold speed. The amount of regenerative braking power requested may be a function of driver demand pedal position, battery state of charge (SOC), vehicle speed, and other conditions. If the driver demand pedal 140 is fully released and vehicle speed is less than a threshold speed, vehicle controller 152 may request a small amount of positive torque/power (e.g., propulsion torque) from propulsion source 105, which may be referred to as creep torque or power. The creep torque or power may allow vehicle 10 to remain stationary when vehicle 10 is on a positive grade.

The human or autonomous driver may also request a negative or regenerative driver demand braking torque, or alternatively a driver demand braking power, via applying brake pedal 150 or via supplying a driver demand braking power request to vehicle control unit 152. Vehicle controller 152 may request that a first portion of the driver demanded braking power be generated via electrified axle 190 and propulsion source 105 via commanding axle control unit 116. Additionally, vehicle controller 152 may request that a portion of the driver demanded braking power be provided via friction brakes 172 via commanding friction brake controller 170 to provide a second portion of the driver requested braking power.

After vehicle controller 152 determines the braking power request, vehicle controller 152 may command axle control unit 116 to deliver the portion of the driver demand braking power allocated to electrified axle 190. Electric power inverter 115 may convert AC electrical power generated by propulsion source 105 into DC power for storage in battery 160. Propulsion source 105 may convert the vehicle's kinetic energy into AC power.

Axle control unit 116 includes predetermined transmission gear shift schedules whereby fixed ratio gears of gear set 107 may be selectively engaged and disengaged. Shift schedules stored in axle control unit 116 may select gear shift points or conditions as a function of driver demand wheel torque and vehicle speed.

Thus, the system of FIG. 1 provides for a system for a vehicle, comprising: a battery pack including a plurality of battery cells; a controller including executable instructions stored in non-transitory memory that cause the controller to generate a corrected state of health for the battery pack, the corrected state of health based on a state of health error of the battery pack. In a first example, the system includes wherein the state of health error is based on a baseline state of battery health. In a second example that may include the first example, the system-further comprises additional executable instructions that cause the controller to adjust vehicle operation in response to the corrected state of health. In a third example that may include one or both of the first and second examples, the system includes wherein the corrected state of health for the battery pack is based on data collected when charging the battery pack. In a fourth example that may include one or more of the first through third examples, the system includes wherein the corrected state of health is a state of health reported by a battery management system plus the state of health error. In a fifth example that may include one or more of the first through fourth examples, the system includes wherein the state of health reported by the battery management system is a feedforward estimate generated by the battery management system. In a sixth example that may include one or more of the first through fifth examples, the system further comprises additional executable instructions to correct a DC resistance value of the battery pack.

Turning now to FIG. 2, a method for determining direct current (DC) resistance for an electric energy storage system (ESS) (e.g., a battery) is shown. The method of FIG. 2 may be incorporated into the system of FIG. 1 as executable instructions that are stored in non-volatile memory (e.g., read-only memory) of a controller (e.g., BMS controller 139 in FIG. 1). The method of FIG. 2 may be performed in cooperation and in conjunction with the system of FIG. 1 and the methods of FIGS. 3 and 4. Additionally, the method may include actions that are taken in the physical world to transform an operating state of the system of FIG. 1 via a controller and/or a human.

At 202, method 200 couples an electric vehicle (EV) to electric vehicle supply equipment (EVSE) (e.g., a charging station) and the vehicle's electric energy storage device management system (EESDMS) or battery management system (BMS) communicates with the EVSE to determine whether or not the electric vehicle is electrically coupled to the EVSE in a desired way and to complete system checks (e.g. the battery is in a state to where it may receive charge). Method 200 proceeds to 204 if electric vehicle system checks pass and if the EVSE is properly coupled to the electric vehicle. Otherwise, method 200 may remain at 202 or exit.

At 204, method 200 measures ESS output voltage before charging current is delivered to the ESS. In one example, the EVSE may determine the ESS output voltage (e.g., an output voltage for the entire battery). Alternatively, method 200 may measure output voltages of each battery cell in the battery. The measured ESS output voltage (V0) and electric current (I0) are stored to controller memory. If individual battery cell voltages and currents are determined, they may be identified by a battery cell numeric indicator Vxxx=(V0) and Ixxx(I0), where Vxxx is a voltage of a battery cell, xxx is a numeric battery cell identifier and each x represents an integer number, V0 is the measured battery cell voltage, Ixxx is electric current of the battery cell, and I0 is the measured battery cell electric current. Method 200 proceeds to 206.

At 206, method 200 begins to apply a maximum current that the ESS may tolerate under present ESS operating conditions for a period of at least 10 seconds. For example, if the ESS has capacity to receive 100 amperes, the EVSE begins to supply 100 amperes to the ESS for a period of 15 seconds. In addition, the BMS measures the ESS output voltage and electric current during the first two seconds that the maximum current is applied to the ESS. For example, the BMS may determine the ESS output voltage 2 seconds after the EVSE begins to supply the maximum amount of current that the ESS may receive. The voltage for the entire battery pack may be V1 and the electric current for the entire battery pack may be I1. If voltages of individual battery cells are to be measured, they may be identified similar to the way that has been mentioned previously. Method 200 proceeds to 208.

At 208, method 200 measures the ESS output voltage and electric current via the BMS at ten seconds after the maximum current is applied to the ESS. For example, the BMS may determine the ESS output voltage 10 seconds after the EVSE begins to supply the maximum amount of current that the ESS may receive. The voltage may be V2 and the electric current may be I2.

It should be noted that values for V0−V2 and currents I0−I2 may be for the entire battery or for individual battery cells. If voltages of individual battery cells and current of individual battery cells are available, V0−V2 and I0−I2 values for each battery cell may be determined along with their corresponding short and long DC resistance values. If voltages of individual battery cells are to be measured, they may be identified similar to the way that has been mentioned previously. The short DC resistance measurement may be a better indication of purely resistive behavior of battery cells while the long DC resistance may be a better indicator of resistive behavior of battery cells and chemical effects of the battery cell. Either the short DC resistance or the long DC resistance may indicate ageing of battery cells. Method 200 proceeds to 210.

At 210, method 200 determines and records to memory actual short DC resistance and actual long DC resistance of the ESS. In one example, the actual short DC resistance for an entire battery may be determined by the following equation: short_DC=(V1−V0)/(I1−I0). If voltages of individual battery cells are measured, their respective short DC resistance values may be determined in a similar way and they may be identified in a way that that has been mentioned previously. This short DC resistance describes a purely resistive value without “Stressed voltage” due to chemical effects of the ESS.

Method 200 also determines the actual long DC resistance of the entire ESS or battery via the following equation: long_DC=(V2−V0)/(I2−I0). If voltages of individual battery cells are measured, their respective long DC resistance values may be determined in a similar way and they may be identified in a way that that has been mentioned previously. This long DC resistance describes a resistive value including “Stressed voltage” due to chemical effects of the ESS. The actual short and long DC resistance values are stored to memory. Method 200 proceeds to 212.

At 212, method 200 optionally evaluates the actual short and long DC resistance (DCR) values of an individual battery cell against the short and long DC resistance values of other individual battery cells. The greatest DC resistance value from the actual short and long DC resistance values may be used to evaluate the BMS SOP value. The actual short DC resistances of each battery cell may be used with actual short DC resistance values of all other battery cells in the ESS to determine an actual average short DC resistance and an actual short DC resistance standard deviation. Similarly, the actual long DC resistances of each battery cell may be used with actual long DC resistance values of all other battery cells in the ESS to determine an actual average long DC resistance and an actual long DC resistance standard deviation.

Indications of battery cell degradations may be generated using a variety of methods to determine non-standard data. These include but are not limited to: a battery cell DCR that is greater than 4 standard deviations from an actual mean DCR (short or long) value; a battery cell DCR that is greater than 1.5*the Inter Quartile Range (IQR); a battery cell above a pre-determined resistance threshold or limit; a battery cell having an actual DCR that is more than 20% above a maximum expected DCR increase at battery cell end of life; and other similar methods of evaluating outliers or defective cells.

Indications of battery cell degradation may be displayed via a human/machine interface and vehicle systems may be adjusted to compensate for battery cell degradation. For example, output of one or more electric machines that provide propulsion power to the electric vehicle may be limited to less than a threshold amount (e.g., constrained to less than 50% of rated output capacity of the electric machine) in response to an indication of one or more battery cells. In another example, if the DC resistance exceeds a threshold resistance, the maximum power output of the battery may be reduced. Method 200 proceeds to 214.

At 214, method 200 compares actual long and short DC resistance values for the entire ESS (e.g., battery) or individual battery cells with predetermined baseline or nominal short DC resistance values for an entire battery pack or individual battery cells that are stored in controller memory. The predetermined baseline or open loop short DC resistance value for the entire battery (e.g., all of the battery's cells that are arranged in series and parallel) or baseline resistance for each of the individual battery cells may be determined from a battery manufacturer's data sheet and a function or table stored in controller memory as shown in FIG. 6. In one example, the comparison may generate one or more error values. For example, an amount of DC resistance error for an ESS (e.g., battery) may be determined from the short DC resistance via the following equation:

$$DCerrshort = DCbase ( time , accur ) - shortDC$$

where DCerrshort is the DC resistance error for the entire ESS (e.g., battery) based on shortDC, DCbase is a function or table in controller memory that returns an expected DC resistance for the entire ESS or an individual battery cell, time is an age of the battery, and accur is the accumulated amount of current that has flowed into and out of the entire ESS or the individual battery cell, and shortDC is the DC resistance for the entire ESS or the individual battery cell. The baseline DC resistance DCbase may be referred to as an open loop or theoretical DC resistance for the entire battery or for the individual battery cells. Alternatively, or in addition, method 200 may determine an amount of DC resistance error for the ESS from the long DC resistance via the following equation:

$$DCerrlong = DCbase ( time , accur ) - longDC$$

where DCerrlong is the DC resistance error for the entire ESS based on longDC. Method 200 proceeds to 216 after determining the DC resistance error for the entire battery (one DC resistance error value) or for each battery cell (a plurality of DC resistance error values). Further, method 200 may report the DCerr value from the equation: DCerr=max (DCerrlong, DCerrshort), where max is a function that returns the greater of DCerrlong and DCerrshort. In this way, the DCerr value may be selected to be the highest DC resistance value so that estimates of other variables generated from the DCerr value may favor lower estimates of battery life so that vehicle owners may be given notice of low battery life in a desirable time frame. Method 200 proceeds to 216.

At 216, method 200 communicates the DC resistance error value for the battery, or values for battery cells, to other routines and/or processes (e.g., the methods of FIGS. 4 and 5) in the BMS. Additionally, method 200 may communicate a SOH error for the battery or SOH errors for battery cells to other routines or processes in the BMS. In one example, an actual or measured SOH may be generated from the actual or measured DC resistance value or values (e.g, shortDC) by referencing a SOH as a function of the DC resistance via a SOH relationship or transfer function. In one example, the relationship or function may be as shown in FIG. 5. The SOH error may be determined via the following equation:

$$SOHerrshort = SOHbase ( Qmax , Cr ) - SOHDC ( shortDC )$$

where SOHerrshort is the state of health error based on shortDC, SOHbase is a baseline or open loop theoretical state of battery health value, Qmax is the maximum charge that may be stored in the battery, Cr is the rated charge capacity of the battery, SOHDC is the measured or actual state of health of the battery as determined from the short DC resistance shortDC. Similarly, SOHerr may be generated from longDC. Additionally, method 200 may report the SOHerr value from the equation: SOHerr=max (SOHerrlong. SOHerrshort), where max is a function that returns the greater of SOHerrlong and SOHerrshort. In this way, the SOHerr value may be selected to be the highest DC resistance value so that SOH errors may be corrected in favor of lower estimates of battery life so that vehicle owners may be given notice of low battery life in a desirable time frame. The baseline state of battery health may be determined from a table or function of empirically determined data that is stored in controller memory and that may be referenced via vehicle operating conditions (e.g., battery age, current sourced and sunk via the battery, etc). Method 200 proceeds to 218.

At 218, method communicates the DC resistance value or DC resistance values to other routines and/or processes in the BMS so that the SOC or SOH value that is generated via the BMS may be corrected according to the actual or measured DC resistance value or values. Method 200 proceeds to exit.

In this way, method 200 may generate an estimate of SOH or estimates of SOH from DC resistance values and a SOH error that may be a basis for updating or not updating the SOH that is reported to other vehicle systems by the BMS. Further, DC resistance values may be communicated to correct SOH estimates. The DC resistance measurement values may also be applied as an early indicator of premature battery ageing or manufacturing anomaly.

As an example of the method of FIG. 2, a battery may be expected to have DC resistance value of 10 milliohm (represented by 100% state of SOH), and may be expected to rise 30% (3 milliohms) over 6 years life (represented by 70% SOH). It may be expected that DC resistance will rise by 0.5 milliohms, (SOH reduced by 5%) per year. In this example, due to vehicle exposures, the BMS communicates a value of 89% after some number of years. Measurements indicate an increase to 11.5 milliohms, or 85% SOP. It may be concluded that the SOP calculation is in error by: BMS degradation=(Reported)/Expected degradation)=(100%−89%)/30%=36.6%; Measured degradation=(Calculated/Expected degradation)=(100%−85%)/30%=50%; BMS degradation is 36.6%−50%=13% less than actual. Alternatively, BMS DCR increase=(10 mohms*(100%−SOH))=(10*(100%−85%))=1.1 milliohms; Measured DCR increase=(10 mohms*(100%−SOP))=(10*(100%−85%))=1.5 milliohms; and BMS degradation is 1.1−1.5/3 milliohms=13% less than actual.

Referring now to FIG. 3, a method for comparing BMS ESS or battery SOH estimates and vehicle based ESS or battery SOH estimates is shown. The method of FIG. 4 may be incorporated into the system of FIG. 1 as executable instructions that are stored in non-volatile memory (e.g., read-only memory) of a controller (e.g., BMS controller 139 in FIG. 1). The method of FIG. 3 may be performed in cooperation and in conjunction with the system of FIG. 1 and the methods of FIG. 2. Additionally, the method may include actions that are taken in the physical world to transform an operating state of the system of FIG. 1 via a controller and/or a human.

At 302, the BMS receives DC resistance (DCR) from the vehicle. In particular, the vehicle controller (e.g., a vehicle control unit or a powertrain control unit) may generate the DC resistance values. The BMS may receive the values via a communications network (e.g., CAN). Method 300 proceeds to 304.

At 304, method 300 judges whether or not to correct one or more SOH estimates that are generated by the BMS. For example, the SOH estimate may be corrected if the SOH error value exceeds a threshold value while vehicle measurement data is within expected threshold ranges. Further, method 300 may require a threshold amount of time between SOH corrections. If method 300 judges that the SOH value is to be corrected, method 300 may correct the SOH value and communicate the corrected SOH value to other vehicle systems (e.g., vehicle controller, electric machine controller, etc.). The battery management system may lower a maximum battery output power in response to a corrected battery state of health that is less than a threshold state of health. For example, a battery pack may have a maximum output of 300 kilo-Watts when a corrected battery state of health is greater than 70%. However, the maximum output of the battery pack may be lowered to 200 kilo-Watts in response to the corrected battery state of health being less than 70%. In one example, the corrected SOH may be generated via the following equation:

$$SOHcorr = SOHbase + SOHerr$$

where SOHcorr is the corrected SOH value, SOHbase is the open loop SOH value reported by the BMS, and SOHerr is the SOH error value. Method 300 proceeds to 306.

At 306, method 300 corrects DCR and communicates the corrected values to other vehicle systems. In one example, the DCR values may be corrected via the following equations:

$$DCRcorr = DCbase + DCerr$$

where DCRcorr is the corrected DC resistance, DCbase is the open loop DC resistance value, DCerr is the DC resistance error. Method 400 communicates the corrected DCR to other vehicle systems. Additionally, in some examples, the vehicle controller may adjust vehicle operation according to the corrected battery state of battery health and/or the corrected DC resistance. For example, the vehicle controller may reduce a maximum rate of battery charging and/or discharging if the corrected battery state of health is reduced to less than a threshold level of of corrected battery DC resistance exceeds a threshold resistance so that battery life may be extended. Additionally, method 300 may display or indicate the battery state of health and/or corrected DC resistance to vehicle users and service persons via a human/machine interface.

In this way, SOH estimates may be corrected via feedback of DCR and charge used to refill the ESS. The corrected SOH and DC resistance values may be more accurate than base values that may be based on ageing models with no feedback mechanism. The improved accuracy may be more significant as the battery ages or in situations where an outside influence may cause pre-mature ageing. The corrected estimates may be communicated throughout the vehicle so that electric machines that provide propulsive effort and other electrical systems may be adjusted (e.g., limit or constrain torque output, limit or constrain power consumed, etc.) based on the corrected values.

Thus, the methods of FIGS. 2 and 3 provide for a method for operating a battery of a vehicle, comprising: estimating a state of health of the battery based on a first resistance value and a second resistance value; and adjusting a maximum output of the battery in response to the state of health. In a first example, the method includes where adjusting the maximum output of the battery includes lowering the maximum output of the battery. In a second example that may include the first example, the method includes where estimating the state of health includes referencing a function via the first resistance value or the second resistance value. In a third example that may include one or both of the first and second examples, the method further comprises generating a resistance value via selecting a greater of the first resistance value and the second resistance value. In a fourth example that may include one or more of the first through third examples, the method includes where estimating the state of health of the battery includes estimating the state of health based on the resistance value. In a fifth example that may include one or more of the first through fourth examples, the method includes where the first resistance value is based on a first voltage of the battery divided by a first current of the battery. In a sixth example that may include one or more of the first through fifth examples, the method includes where the first voltage and the first current are measured a first predetermined amount of time since beginning to supply a maximum current of the battery from the battery. In a seventh example that may include one or more of the first through sixth examples, the method includes where the second resistance value is based on a second voltage of the battery divided by a second current of the battery, the second voltage of the battery different than the first voltage.

The methods of FIGS. 2 and 3 also provide for a method for operating a battery of a vehicle, comprising: estimating a DC resistance of the battery based on data collected when charging the battery; and adjusting a maximum output of the battery in response to the DC resistance of the battery. In a first example, the method includes where the DC resistance is estimated via a battery voltage and a battery current. In a second example that may include the first example, the method further comprises generating a DC resistance error. In a third example that may include one or both of the first and second examples, the method further comprises generating a battery state of health via the DC resistance. In a fourth example that may include one or more of the first through third examples, the method further comprises generating a battery state of health error via the DC resistance.

Referring now to FIG. 4, a plot that shows a relationship between battery DC resistance and battery SOH is shown. The vertical axis represents SOH and SOH increases in the direction of the vertical axis arrow. The horizontal axis represents battery DC resistance and battery DC resistance increases in the direction of the horizontal axis arrow. Line 402 describes the relationship between battery DC resistance and battery state of health. It may be observed that battery SOH decreases as battery DC resistance increases. A representation of the plot in FIG. 4 may be stored in controller memory as a function and the function may be referenced or indexed by battery DC resistance. The function outputs an estimate of battery SOH.

Referring now to FIG. 5, a block diagram for generating an open loop or feedforward estimate of DC resistance of a battery is shown. Block 502 represents a model and the model outputs DC resistance of a battery cell based on inputs of time since battery manufacture, total energy flow into and out of the battery, and battery temperature. The model may be an empirically determined model that may be generated by monitoring battery operation while charging and discharging the battery. Alternatively, the model may be a mathematical representation of DC resistance.

Turning now to FIG. 6, an example table for determining base or baseline battery resistance is shown. In this example, table 600 is referenced via battery age (e.g., cumulative amount of time since battery pack manufacture) via the vertical axis. Table 600 is also referenced by the cumulative amount of electric current that has entered and exited the battery pack via the horizontal axis. The entries in the cells 602 of the table may be empirically determined via aging and measuring battery pack DC resistance as the battery pack ages and as the amount of electric current flowing into and out of the battery pack increases.

Note that the example control and estimation routines included herein can be used with various powertrain and/or vehicle system configurations. The control methods and routines disclosed herein may be stored as executable instructions in non-transitory memory and may be carried out by the control system including the controller in combination with the various sensors, actuators, and other transmission and/or vehicle hardware. Further, portions of the methods may be physical actions taken in the real world to change a state of a device. Thus, the described actions, operations and/or functions may graphically represent code to be programmed into non-transitory memory of the computer readable storage medium in the vehicle and/or transmission control system. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example examples described herein, but is provided for ease of illustration and description. One or more of the illustrated actions, operations and/or functions may be repeatedly performed depending on the particular strategy being used. One or more of the method steps described herein may be omitted if desired.

While various embodiments have been described above, it is to be understood that they have been presented by way of example, and not limitation. It will be apparent to persons skilled in the relevant arts that the disclosed subject matter may be embodied in other specific forms without departing from the spirit of the subject matter. The embodiments described above are therefore to be considered in all respects as illustrative, not restrictive. As such, the configurations and routines disclosed herein are exemplary in nature, and that these specific examples are not to be considered in a limiting sense, because numerous variations are possible. For example, the above technology can be applied to powertrains that include different types of propulsion sources including different types of electric machines, internal combustion engines, and/or transmissions. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims may be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A method for operating a battery of a vehicle, comprising:
estimating a state of health of the battery based on a first resistance value and a second resistance value; and
adjusting a maximum output of the battery in response to the state of health.

2. The method of claim 1, where adjusting the maximum output of the battery includes lowering the maximum output of the battery.

3. The method of claim 1, where estimating the state of health includes referencing a function via the first resistance value or the second resistance value.

4. The method of claim 1, further comprising generating a resistance value via selecting a greater of the first resistance value and the second resistance value.

5. The method of claim 4, where estimating the state of health of the battery includes estimating the state of health based on the resistance value.

6. The method of claim 1, where the first resistance value is based on a first voltage of the battery divided by a first current of the battery.

7. The method of claim 6, where the first voltage and the first current are measured a first predetermined amount of time since beginning to supply a maximum current of the battery from the battery.

8. The method of claim 7, where the second resistance value is based on a second voltage of the battery divided by a second current of the battery, the second voltage of the battery different than the first voltage.

9. A system for a vehicle, comprising:
a battery pack including a plurality of battery cells;
a controller including executable instructions stored in non-transitory memory that cause the controller to generate a corrected state of health for the battery pack, the corrected state of health based on a state of health error of the battery pack.

10. The system of claim 9, wherein the state of health error is based on a baseline state of health.

11. The system of claim 10, further comprising additional executable instructions that cause the controller to adjust vehicle operation in response to the corrected state of health.

12. The system of claim 9, wherein the corrected state of health for the battery pack is based on data collected when charging the battery pack.

13. The system of claim 9, wherein the corrected state of health is a state of health reported by a battery management system plus the state of health error.

14. The system of claim 13, wherein the state of health reported by the battery management system is a feedforward estimate generated by the battery management system.

15. The system of claim 13, further comprising additional executable instructions to correct a DC resistance value of the battery pack.

16. A method for operating a battery of a vehicle, comprising:
estimating a DC resistance of the battery based on data collected when charging the battery; and
adjusting a maximum output of the battery in response to the DC resistance of the battery.

17. The method of claim 16, where the DC resistance is estimated via a battery voltage and a battery current.

18. The method of claim 16, further comprising generating a DC resistance error.

19. The method of claim 18, further comprising generating a battery state of health via the DC resistance.

20. The method of claim 16, further comprising generating a battery state of health error via the DC resistance.
